(19) United States
(12) Patent Application Publication
(10) Pub. No.: US 2017/0077522 A1
(43) Pub. Date: Mar. 16, 2017

(54) STRAIN ENHANCEMENT OF FUNCTIONAL OXYGEN DEFECTS IN ELECTROCHEMICAL METAL OXIDES

(71) Applicant: UT-BATTELLE, LLC, OAK RIDGE, TN (US)

(72) Inventors: Gyula ERES, Knoxville, TN (US); Ho Nyung LEE, Oak Ridge, TN (US); Fernando A. REBOREDO, Knoxville, TN (US); Woo Seok CHOI, Knoxville, TN (US); John W. FREELAND, Lemont, IL (US); Hyoung Jeen JEEN, Knoxville, TN (US); Tricia L. MEYER, Knoxville, TN (US); Chandrima MITRA, Oak Ridge, TN (US); Jonathan R. PETRIE, Oak Ridge, TN (US)

(73) Assignee: UT-BATTELLE, LLC, OAK RIDGE, TN (US)

(21) Appl. No.: 15/263,125

(22) Filed: Sep. 12, 2016

Related U.S. Application Data
(60) Provisional application No. 62/216,427, filed on Sep. 10, 2015.

(51) Int. Cl. H01M 4/90; C30B 29/22; C30B 33/02

(52) U.S. Cl. CPC H01M 4/9033; C30B 33/02; C30B 29/22

(57) ABSTRACT

Methods for tailoring an oxygen defect concentration, such as oxygen vacancies, in a transition metal oxide and the resulting materials are provided. An epitaxial strain, such as in the form of a biaxial tensile strain of up to 5%, is applied to the transition metal oxide to increase the oxygen defect concentration in the transition metal oxide to result in a product comprising the transition metal oxide having an increased oxygen defect concentration.

### CROSS REFERENCE TO RELATED APPLICATION

This application claims the benefit of and priority to U.S. Provisional Application No. 62/216,427, filed on 10 Sep. 2015, the entirety of which application is incorporated herein by reference.

### GOVERNMENT RIGHTS

This invention was made with government support under Contract No. DE-AC05-00OR22725 awarded by the U.S. Department of Energy. The government has certain rights in the invention.

### FIELD OF THE INVENTION

The present invention relates generally metal oxides and, more particularly to strain enhancement of functional oxygen defects in electrochemical metal oxides.

### BACKGROUND OF THE INVENTION

Oxygen defects play an ever-expanding role in the development of functional materials essential to a wide range of technologies, for example, driving advances in a variety of green technologies, such as ranging from energy storage to superconductivity.

Originally seen as undesirable and detrimental to the performance of oxide materials, the formation of oxygen vacancies in some oxides has become increasingly important due to the realization that these same defects can lead to new functional phenomena. For example, incremental changes in oxygen vacancies can leverage large shifts in magnetic, electronic, and/or catalytic properties in transition metal oxides (TMOs) without introducing possible impurities and segregation associated with heterovalent cation doping. Moreover, the functional manipulation of oxygen vacancies is critical for various key information, energy, and environmental technologies, including high Tc superconductors, colossal magnetoresistive materials, oxygen membranes, catalytic converters, memristors, energy storage devices, and other electrochemical devices, for example.

Traditionally, the only methods to control these defects have included either heterovalent cation doping or simple reliance on environmental thermodynamic variables, e.g., oxygen partial pressure, temperature, etc. The doping of oxides, however, raises complicated issues such as relating to purity and segregation, leaving environmental or atmospheric control as the only reliable alternative to dictate oxygen stoichiometry. The determination of oxygen stoichiometry via environment manipulation is not, however, necessarily conducive to the optimal functionalization of oxygen vacancies in said environment. In particular, robust oxygen stoichiometry in bulk materials at reduced temperatures (<600° C.) and oxidizing conditions, e.g., high electrochemical potentials, severely limits the functionality of these defects in useful electrochemical devices, such as in metal air batteries and solid oxide fuel cells (SOFCs), where oxygen vacancies can help catalyze oxygen evolution and reduction. To facilitate the use of TMOs in much more varied conditions, control or manipulation through or via another parameter is desired or required to alleviate dependence of oxygen stoichiometry on the external environment and to permit or allow more precise control of functional oxygen defects in various applications and wherever the oxide is located.

### SUMMARY OF THE INVENTION

The present invention provides methods for tailoring oxygen defect concentration in a material as well as materials with such tailored oxygen defect concentration.

As detailed below, in accordance with one aspect of the subject development, epitaxial strain can be used to precisely tailor the concentration of oxygen defects in TMOs at low to moderate temperatures (e.g., 25-600° C.). Under such conditions, oxygen defects, such as oxygen vacancies, can enhance catalytic activities critical for example, to electrochemical devices, including alkaline fuel cells and batteries. Further, using strontium cobaltite (SrCoO_{3-δ}) oxygen sponges, single crystalline thin films with a deliberately controlled oxygen content can be epitaxially stabilized due to strain-induced changes in oxygen vacancy activation energies. To further demonstrate the immediate advantages of such tunability and tuning, a small biaxial tensile strain (up to 5%) can be applied to artificially increase the vacancy concentration in SrCoO_{3-δ} at the conditions required for the catalytic oxygen evolution reaction (OER), which fully oxidizes unstrained strontium cobaltite. Due to the higher oxygen vacancy concentration, the catalytic activity of the cobaltite was drastically improved by over an order of magnitude. Such OER activities are found to greatly surpass the catalytic performance of a noble metal catalyst, Pt, and are comparable to that of state-of-the-art Ir0₂ when highly strained. Thus, at least one aspect of the development relates to new methods or techniques for designing a new class of advanced oxide materials where strain, and not doping or ambient conditions, is the key tuning parameter of functional oxygen defects.

In one aspect, a method for tailoring an oxygen defect concentration in a transition metal oxide is provided. In one embodiment, such a method may involve applying an epitaxial strain of up to 5% to the transition metal oxide to increase the oxygen defect concentration in the transition metal oxide and result in a product comprising the transition metal oxide having an increased oxygen defect concentration. In one embodiment, such a method may involve applying an epitaxial strain of up to 5% to the transition metal oxide to increase the oxygen defect concentration in the transition metal oxide with the application of the strain desirably or suitably controlled, e.g., increased, maintained, etc., to result in a product comprising the transition metal oxide having an increased oxygen defect concentration.

In another aspect, a method for increasing an oxygen vacancy concentration in a transition metal oxide is provided. In one embodiment, such a method involves providing a thin film of the transition metal oxide on a substrate. A biaxial tensile strain of up to 5% is applied to the thin film to increase the oxygen vacancy concentration in the transition metal oxide. The application of the strain results in a product comprising the TMO having an increased oxygen vacancy concentration. In one embodiment, such a method involves providing a thin film of the transition metal oxide on a substrate. A biaxial tensile strain of up to 5% is applied to the thin film to increase the oxygen vacancy concentration in the transition metal oxide with the application of the strain desirably or suitably controlled, e.g., increased, maintained, etc., to result in a product comprising the transition metal oxide having an increased oxygen defect concentration.

Such methods can be applied to produce catalyst, such as an oxygen evolution reaction catalyst, for example.

Those skilled in the art and guided by the teachings herein provided will understand and appreciate that “strain” (e.g., tensile strain or compressive strain) may be introduced to a material using any suitable method. For example, strain can be introduced via mechanical, thermal, geometric, and/or chemical means, or combinations thereof. In some embodiments, introducing a strain comprises forming a layer of the material over a substrate. In some cases, the lattice parameter of the material and the lattice parameter of the substrate are different. The difference in the lattice parameter may lead to a strain in the material formed over the substrate. For example, in some embodiments, forming a layer of material over a substrate comprises epitaxially growing a layer of the material on the substrate. The differences in the lattice parameters of the epitaxial film and the substrate will cause a strain to be introduced into the epitaxial film.

As used herein, measurements of “strain” are to be generally understood as referring to strain such as calculated by:

$$strain ( \% ) = \frac{( Δ L )}{L} \times 100 \% = \frac{( l - L )}{L} \times 100 \% \qquad ( 1 )$$

where l is the length of the measured dimension in the strained state, and L is the length of the measured dimension in the unstrained state. The lengths used to calculate strain may be measured, for example, by using X-ray diffraction to measure lattice parameters.

Other objects and advantages will be apparent to those skilled in the art from the following detailed description taken in conjunction with the appended claims and drawings.

### BRIEF DESCRIPTION OF THE DRAWINGS

The above-mentioned as well as other features and objects of the invention will be better understood from the following detailed description taken in conjunction with the drawings wherein:

FIG. 1a and FIG. 1b present data concerning the evolution of OER activity with epitaxial stain, with FIG. 1a presenting polarization curves at 5 mV/s for the OER reaction in O₂-sat. 0.1 M KOH on P-SCO under increasing amounts of biaxial tensile strain and FIG. 1b presenting current densities at 1.6 V vs RHE plotted as a function of strain for the films, plotted as a function of strain.

FIG. 2a and FIG. 2b present data concerning strain control of oxygen stoichiometry in epitaxial P-SCO, with FIG. 2a presenting XRD θ-2θ scans around the 002 peak of topotactically oxidized P-SCO films on different substrate materials and FIG. 2b presents unit cell volume as a function of biaxial strain for either annealed or electrochemically oxidized BM-SCO films to P-SCO.

FIG. 3a, FIG. 3b and FIG. 3c present evidence concerning preferential oxygen loss in tensile strained P-SCO, with FIG. 3a presenting intensity versus energy data for the O-K edge of annealed P-SCO on LSAT (ε=1.0%) through KTO (ε=4.2%) substrates; FIG. 3b presenting intensity versus energy data for the Co-L_{2,3} edge of annealed P-SCO on LSAT (ε=1.0%) through KTO (ε=4.2%) substrates; and FIG. 3c presenting resistivity of P-SCO as a function of temperature data for the topotactically oxidized SCO films shown in FIG. 1a.

FIG. 4a and FIG. 4b present data regarding strain dependent oxygen activation energies, with FIG. 4a presenting the calculated activation energy (Eₐ) for oxygen ion movement in BM-SCO to understand the topotactic oxidation to P-SCO and FIG. 4b presenting a summary of the activation energy barrier (ΔEₐ) and intercalation enthalpy (Hi) as a function of strain.

### DETAILED DESCRIPTION OF THE INVENTION

One aspect of the present development concerns the use of epitaxial strain as a new parameter in controlling oxygen stoichiometry, particularly in thin film TMOs such as in order to facilitate heterocatalytic activities at low to moderate temperatures (up to ˜600° C.) in either gaseous or aqueous environments.

Strontium cobaltite, SrCoOₓ (SCO), has sparked interest due to the discovery of a low-temperature topotactic transition between the brownmillerite phase SrCoO_{2.5}, denoted as BM-SCO, and perovskite phase SrCoO_{3-δ}, denoted as P-SCO, where 0≦δ≦0.25. Due to the easy motion of O²⁻ in BM-SCO offered by the open framework and metastability of Co⁴⁺ in P-SCO, the cobaltite has exceptionally low oxygen activation energies (<1 eV), amplifying the effects of energetic shifts caused by strain. Since the fast, reversible Co³⁺/Co⁴⁺ couple offered by these materials promote redox reactions, epitaxial SCO oxygen sponges reveal enhanced catalytic activities towards CO oxidation at ˜300° C. as well as a significant oxygen exchange coefficient at lower temperatures, rendering these films attractive for electrochemical sensors and SOFCs. The combination of catalytic potential and such low energetic thresholds for oxygen control make SCO films an ideal platform for systematically studying strain-induced oxygen non-stoichiometry in these oxides and its resultant effects on catalysis.

Those skilled in the art and guided by the teachings herein provide will understand and appreciate that while the invention will be further described in detail below making specific reference to strontium cobaltite, SrCoOₓ (SCO), the broader practice of the invention is not necessarily limited to specific or particular TMOs as the invention has application to or practice with various TMOs including, for example, CaCoOₓ, CaFeOₓ, SrFeOₓ, LaNiOₓ, LaMnOₓ, and SrMnOₓ.

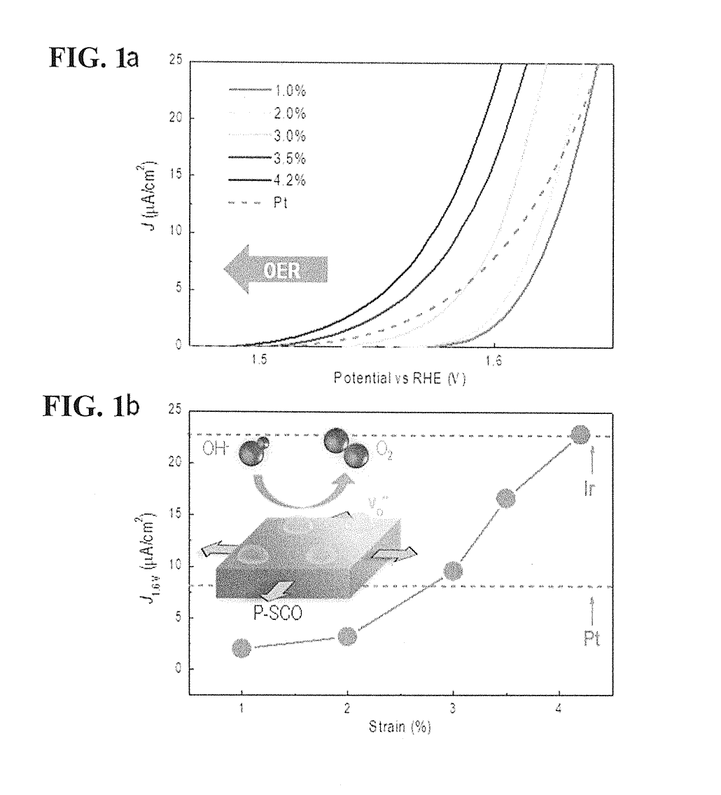

In one embodiment, pulsed laser epitaxy (PLE) was used to deposit multivalent oxygen sponges SrCoO_{3-δ},son various substrates that would induce varying amounts of compressive or tensile strain on the films. By a combination of one or more of x-ray diffraction, x-ray absorption, electrical transport, and computational calculations, compressive strain was found to significantly raise the thermodynamic barrier for oxygen motion out of the films, while tensile strain lowered it. The application of tensile strain allows for a purposeful reduction of the oxygen stoichiometry in SrCoO_{3-δ} at highly anodic potentials in an alkaline solution (1.6 V vs RHE in 0.1 M KOH) that would otherwise fully oxidize unstrained SrCoO_{3-δ}. As shown in FIG. 1a and FIG. 1b, this strain coupling enables functionalization of oxygen vacancies near the surface that dramatically enhance the oxygen evolution reaction (OER) by over an order of magnitude, equaling or surpassing the activity of noble metal catalysts. As shown in the example, introducing epitaxial strain as a thermodynamic parameter in controlling oxygen stoichiometry in TMOs will desirably lead to a new generation of novel energy materials and devices.

Turning to FIG. 1a and FIG. 1b, there is presented data concerning the evolution of OER activity with epitaxial stain. More particularly, FIG. 1a is a graphical presentation of polarization curves at 5 mV/s for the OER reaction in O₂-sat. 0.1 M KOH on P-SCO under increasing amounts of biaxial tensile strain. As shown, there is a clear trend towards higher activity as this strain results in an increase in functional oxygen vacancy defects. FIG. 1b is a graphical presentation of current densities at 1.6 V vs RHE plotted as a function of strain for the films. As shown, the application of approximately 4% tensile strain resulted in an increase of oxygen vacancies near the surface (translucent hemispheres in schematic) responsible for over a 1000% rise in OER activity. The activity for a textured (111) Pt film is included as a reference. Note that since state-of-the-art Ir catalysts are known to perform ˜3 time better than Pt, comparable activity for SrCoOₓ when highly strained is expected.

As will be appreciated by those skilled in the art and guided by the teachings herein provided, any suitable amount of strain can be applied to a material constructed and arranged, in accordance with the embodiments described herein. In some embodiments, the absolute value of the strain of the material measured relative to an unstrained sample of the material at room temperature, is at least about 0.01%, at least about 0.05%, at least about 0.1%, at least about 0.5%, at least about 1%, at least about 2%, at least about 3%, up to about 4.2%, and up to about 5%.

The present invention is described in further detail in connection with the following examples which illustrate or simulate various aspects involved in the practice of the invention. It is to be understood that all changes that come within the spirit of the invention are desired to be protected and thus the invention is not to be construed as limited by these examples.

Methods

Epitaxial films of BM-SCO and P-SCO were grown 15-nm thick on different substrates through pulsed laser epitaxy (PLE). The BM-SCO growth temperature, oxygen partial pressure, laser fluence, and repetition rate were fixed at 750° C., 100 mTorr, 1.5 J/cm², and 5 Hz, respectively. For annealing in-situ, the as-deposited BM-SCO films were cooled under 100 mTorr of O₂ to 300° C. before introducing 500 Torr O₂ into the chamber to topotactically oxidize the films for 5 minutes. P-SCO_{ozone} films were grown under the same conditions with the exception of the partial pressure, which was 200 mTorr of a mix of O₂+O₃ (5%). BM-SCO films for electrochemical oxidation were initially grown under the same conditions as the annealed films on 10 nm-thick La_{0.8}Sr_{0.2}MnO₃ (LSMO) underlayers.

The electrochemical oxidation of BM-SCO was performed in a 150 ml solution of O₂-saturated 0.1 M KOH developed with Sigma-Aldrich KOH pellets and Milli-Q water. A three-electrode setup was used with a Pt counter electrode and standard calomel (SCE) reference electrode. Electrical connectivity was made to the LSMO underlayer and an epoxy was employed to expose only the SCO surface to solution. Potential was applied via a Biologic SP-200 Potentiostat. Ohmic losses were determined via a high frequency (˜100 kHz) impedance measurement and subtracted from the applied potential. The potential was ramped at 10 mV/s from 1.0 V to 1.6 V and held for 5 minutes to ascertain a steady state stoichiometry. No peaks indicative of solution in contact with the LSMO underlayer were observed.

The same electrochemically oxidized films were used for OER measurements. Before determining the OER current, the potential was cycled at least 10 times at 50 mV/s between 1.0 and 1.65 V to expose a stable surface under these conditions. Linear voltammetry sweeps to determine OER steady-state polarization curves ranged from 1.0 to 1.65 V at 5 mV/s and were repeated at least three times to ensure reproducibility. Above ˜1.5 V vs RHE, all anodic currents were attributed to oxygen evolution as further anodic peaks associated with continued P-SCO oxidation were not established in either O₂₋ or Ar-saturated solutions. Specific surface area measurements to minimize effects due to increase active sites were determined on the oxidized P-SCO films via double-layencapacitance measurements around the open-circuit potential (OCP). These measurements produce a systematic surface area used in comparing relative OER activities. To compare activities to a noble metal, a highly (111) textured Pt film (100 nm in thickness) was sputter deposited at room temperature onto a (001) STO substrate.

The sample structure was characterized with a high-resolution four circle XRD. Temperature-dependent dc transport measurements were conducted using the van der Pauw geometry with a 14 T Physical Property Measurement System (PPMS). Optical spectroscopy was performed using a spectroscopic ellipsometer between 1.25 and 5.00 eV at an incident angle of 70°. A simple two-layer model (film/substrate) was used to extract dielectric functions and optical conductivity. Valence state and oxygen stoichiometry via XAS were performed at the beamline 4-ID-C of the Advanced Photon Source at Argonne National Laboratory.

Modeling calculations were performed within density functional theory (DFT) employing the Vienna Ab-initio Simulations Package (VASP) code and 2×2×1 supercells containing 144 atoms. Projector-augmented wave pseudopotentials were used with an energy cut of 600 eV. The activation energy (Eₐ) barriers (ΔEₐ) for oxygen ions and the intermediate transition states were computed using the Nudged Elastic Band (NEB) method as implemented in the VASP code. The energy barriers were optimized until the forces on each image was converged to 0.004 eV/A. In order to account for strong correlations, the cobalt d orbitals were treated within the local spin density (LSD) approximation with Hubbard U corrections. A U value of 7.5 eV was chosen, the electronic structure of which matched closely to those computed with the Hybrid Scuzeria Emzerhof (HSE) functional.

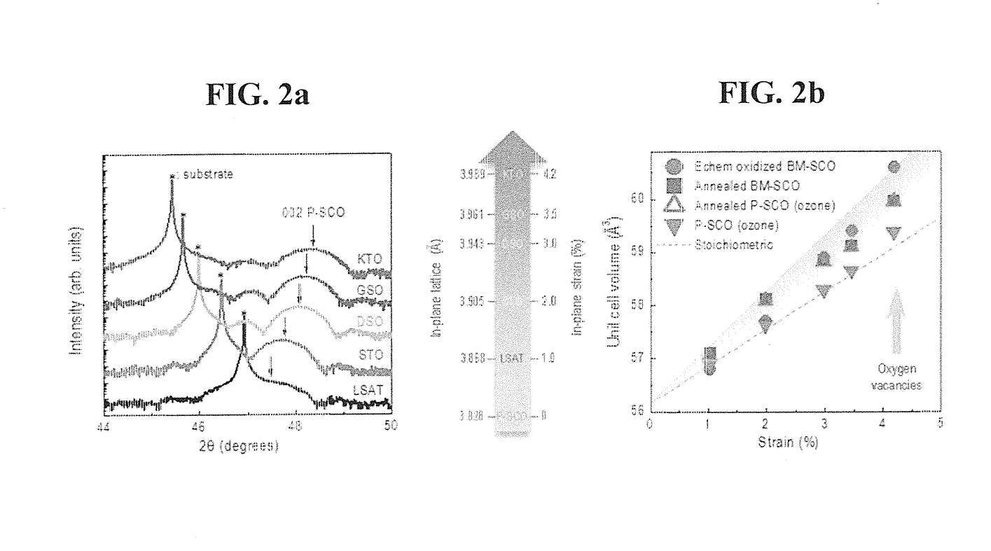

Several sets of SCO films were epitaxially grown on lattice-mismatched substrates using (PLE). All films had uniform film thicknesses of 15 nm to ensure no strain relaxation on various perovskite substrates. The substrates included (001) (LaAlO₃)_{0.3}-(SrAl_{0.5}TaO₃)_{0.7} (LSAT), (001) SrTiO₃ (STO), (110) DyScO₃ (DSO), (110) GdScO₃ (GSO), and (001) KTaO₃ (KTO), whose pseudo-cubic parameters varied, respectively, from a_{sub}=3.868 to 3.989 Å (see FIG. 2a). While BM-SCO is orthorhombic (aₒ=5.574, bₒ=5.447, cₒ=15.745 Å), it is here represented as pseudo-tetragonal (aₜ=3.905, cₜ/4=3.936 Å). The stoichiometric P-SCO, on the other hand, is cubic with a_{c}=3.829 Å, leading to substrate-induced lattice mismatches from 1.0 to 4.2%, as shown in FIG. 2b. In order to utilize the metastable nature of cobaltites—note that the metastable nature of SCO makes this class of materials more attractive for electrochemical applications—perovskite phase thin films were prepared by various approaches known to result in a fully oxidized unstrained state: (1) In-situ topotactic oxidation from BM-SCO to P-SCO by annealing at 300° C. in 500 Torr of O₂ for 5 minutes (see FIG. 2), (2) Direct growth of stoichiometric P-SCO in ozone (P-SCO_{ozone}), followed by the same annealing step as in (1) to reach an equilibrium oxygen concentration depending on the strain state (FIGS. 2b), and (3) Ex-situ electrochemical oxidation of BM-SCO films to P-SCO in an alkaline solution (FIG. 2b). The electrochemically treated BM-SCO films were initially deposited on a 10 nm La_{0.8}Sr_{0.2}MnO₃ (LSMO) conducting bottom electrode to ensure uniform charge transport throughout the nm-thick cobaltite layer XRD reciprocal space mapping confirmed that all used perovskite films were coherently strained.

FIG. 2a shows an example of our observation that strain can modulate oxygen stoichiometry in epitaxial P-SCO films that have undergone topotactic oxidation. The XRD θ-2θ scans of around the P-SCO 002 peak for annealed BM-SCO on various substrates are given. Each perovskite peak is clearly defined with Kiessig fringes that verify the superior film quality. However, upon careful inspection of the out-of-plane lattice constant, the monotonic shift in the out-of-plane lattice parameter with tensile strain cannot be simply understood through a Poisson-type contraction due to substrate-induced tensile strain. Therefore, the possibility of lattice expansion due to increased vacancy formation as the film deviates from the stoichiometric δ=0 P-SCO phase in SrCoO_{3-δ} was considered. The unit cell volume of these annealed films was compared to the as-grown P-SCO_{ozone} films, which have essentially stoichiometric concentrations of oxygen. As seen in FIG. 2b, the unit cell volume of the P-SCO_{ozone} films increased monotonically with strain. This increase was readily fit to a dashed line ascribing all linear expansion to a Poisson ratio of v˜0.27, which is a common value associated with cobaltites. The topotactically oxidized P-SCO films, however, exhibited a larger lattice volume than that of as-grown P-SCO_{ozone}. This deviation became more pronounced when the tensile strain increased. As summarized in FIG. 2b, this increased unit cell volume was observed from P-SCO samples prepared by either annealing BM-SCO or P-SCO_{ozone}, indicating a steady-state vacancy concentration attained through, respectively, either the intercalation or deintercalation of oxygen.

As the increase in the oxygen vacancies often results in lattice expansion for perovskite-typed complex oxides, this deviation to the greater oxygen deficiency in the films was attributed to or with tensile strain; otherwise, an unrealistic v=0.17 would be required from fully oxygenated films to fit the experimental data. A similar trend was seen for the electrochemically oxidized BM-SCO. Moreover, higher tensile strains required higher anodic potentials to complete the topotactic transformation from BM-SCO to a more oxygenated P-SCO, indicating an increasing preference for oxygen vacancies with such strain.

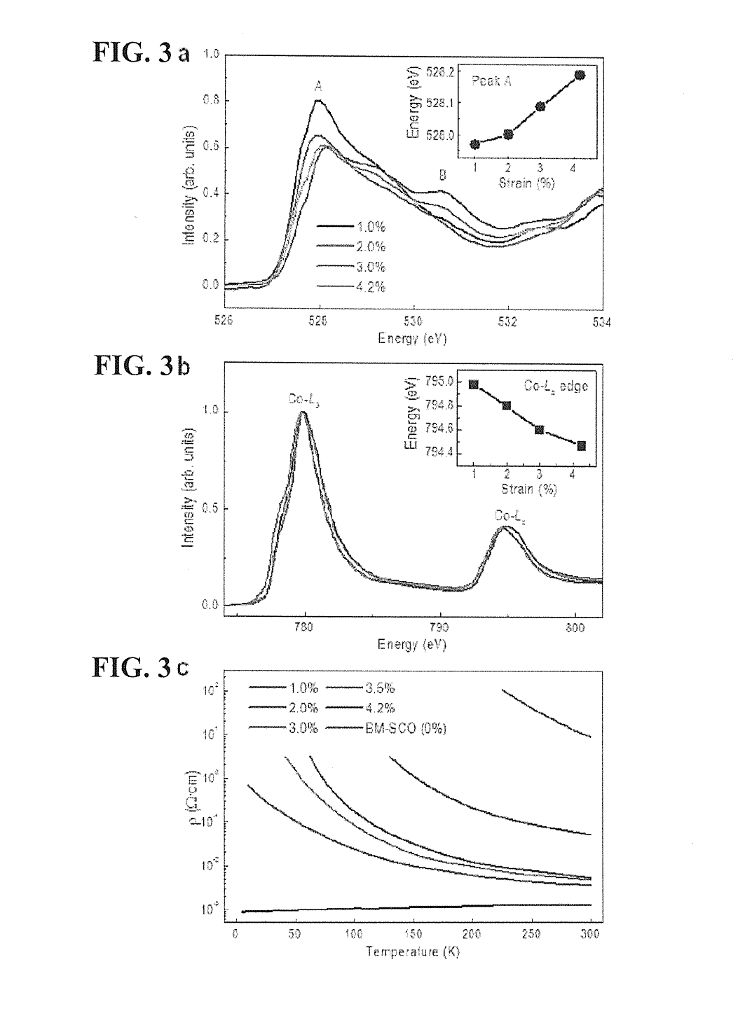

To confirm that the oxygen stoichiometry in the film varies as the tensile strain w a s increased, the topotactically oxidized P-SCO films were investigated via x-ray absorption spectroscopy (XAS) using both the O K- and Co L-edges. As shown in FIG. 3a, there are two peaks of note in the pre-peak region of the O K-edge. These peaks are labeled A and B and are linked to Co 3d-O 2p hybridization from hole states associated, respectively, with either fully oxidized or partially oxidized coordination. While the intensity of Peak B increased under tensile strain with oxygen loss, peak A substantially diminished as less intercalated oxygen translated into an oxygen deficient state. Peak A also shifted to higher photon energies with oxygen loss as a result of negative charge-transfer. The shift of 0.2 eV as strain increased to 4.2% is consistent with the transition from SrCoO_{2.9} to SrCoO_{2.75} determined in previous studies for bulk P-SCO.

An investigation of the Co-L edge in FIG. 3b also indicated a changing valence state with increasing amounts of oxygen vacancies at higher tensile strains. The shift in intensity of the Co-L_{2,3} peaks towards lower energies confirmed that there indeed was a decrease in the average transition metal valency from Co⁴⁺ with increasing strain. The chemical shift in the Co-L₂ edge between the ε=1.0 and 4.2% films is −0.4 eV. A related −1 eV shift in the Co-L₂ edge can be seen in the (La₁₋ₓSrₓ)CoO₃ system when one electron is transferred away from Co as the Sr concentration varies from x=1 to x=0. Using this shift, a transfer of up to 0.4 e− was estimated which is compatible with Δδ≦0.20 as the equilibrium state transitions from SrCoO_{2.9} to SrCoO_{2.75} with tensile strain.

Electrical dc transport measurements (see FIG. 3 c) further support the systematic change in stoichiometry with strain. As the tensile strain increased, the film became less conducting, suggesting a higher oxygen vacancy concentration. The origin for the less conducting behavior under tensile strain has not been completely understood. Indeed, while the systematic trend is obvious, the more insulating nature of the films except for the 1% strained film (δ≦0.1) indicates that the carrier transport is strongly influenced by the change in strain-induced carrier concentration owing to the loss of oxygen. On the other hand, an optical spectroscopic study revealed that even the highly insulating P-SCO film on STO maintains similar features as compared to the metallic P-SCO on LSAT. As the optical measurement depicts the properties of the whole film without any contributions from contact resistance or domain boundaries, it was concluded that the P-SCO thin films are at the verge of the percolation limit with a possible coexistence of metallic (P-SCO) and insulating (BM-SCO) phases.

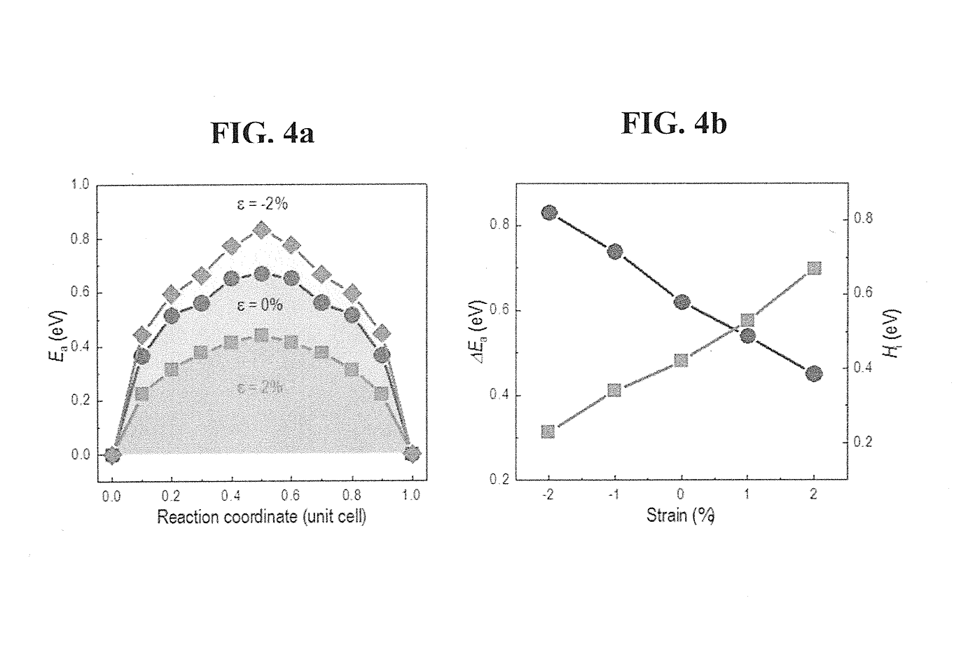

To better understand the experimental observation of the strong coupling between strain and oxygen stoichiometry, first-principles Density Functional Theory (DFT) calculations were performed. Two quantities as a function of strain were specifically computed. The first w a s the activation energy barrier, ΔEₐ, which is the energy required for an oxygen atom to diffuse from one site to another along vacancy channels in the open network structure. The other was the formation enthalpy, Hi, to intercalate an oxygen atom into one of the vacancy sites. As shown in FIG. 4a, tensile strain reduced ΔEₐ, whereas compressive strain raised (believed due to changes in the stabilizing effects of hybridization between Co 3d and O2p, which are dependent on Co-O bond length). It is worth stressing that by applying only a 2% tensile strain, one can reduce ΔEₐ by ˜30%. Concurrent with the strain-induced changes in ΔEₐ, as shown in FIG. 4b, Hi rises with tensile strain and falls with compressive strain, respectively suggesting either greater or smaller thermodynamic instability towards oxygen incorporation. Both values indicate that the application of tensile strain significantly facilitates oxygen vacancy generation, whereas compressive strain prevents the system from losing oxygen.

To demonstrate the advantage of using strain to control oxygen stoichiometry, the effect of strain on the OER catalysis of SCO in the oxidizing environment typically found in metal-air batteries and water-splitting reactions was studied . Recent studies have shown that oxygen vacancies near the oxide surface help catalyze the alkaline OER reaction due to an increase in the number of active sites around these defects, a weaker metal-oxygen bond yielding a faster intermediate exchange, and vacancy-induced electron-doping that changes the spin configuration for more efficient electron transfer. Therefore, we anticipated that the independent tuning of oxygen content via strain would allow us to manipulate these oxygen defects to enhance the OER activity.

As shown in FIG. 1a, the current density [J(V)] associated with the OER was plotted for P-SCO under different degrees of tensile strain. As the tensile strain was increased from 1.0 to 4.2%, the onset potential for OER was reduced by ˜100 mV towards the thermodynamic limit of 1.22 V vs. RHE. Since commercial catalysts require overpotentials of 0.3-0.4 V beyond the thermodynamic limit for practical operation, we compared the activity of these films by observing J at 1.6 V. As represented in FIG. 1b, these activities rose by over an order of magnitude for films containing increased oxygen vacancies via application of tensile strain. By surpassing the dashed line, which indicates J of a comparatively measured 100 nm film of Pt, such drastic changes in J resulted in films with strains >3% exceeding the activity of a well-known oxygen electrocatalyst in fuel cells and batteries. In fact, these results place P-SCO with 3-4.2% strain at the same level with the leading platinum metal group competitors for OER catalysis. Additionally, the inverse relationship between conductivity and activity suggests charge transfer considerations are not hindering the OER reaction on these perovskites. It is further noted that such dramatically enhanced catalytic activity essential for splitting water and evolving O₂ was achieved by purposefully using strain to maintain an oxygen deficient state even in a highly oxidizing environment.

While the aspects of the subject development have been described above making reference to examples wherein “thin” films were of or had a uniform film thicknesses of 15 nm, those skilled in the art and guided by the teachings herein provided will understand and appreciate that the broader practice of the subject development is not necessarily so limited. As the development can be suitably practiced with thin films of other appropriate thicknesses which are thin enough to maintain a fully strained state without losing the coherent lattice match between the film and the substrate. This is typically within 100 nm in thickness for the lattice mismatch up to 5%. Film thickness uniformity is less than 10%, corresponding to the surface roughness of 10 nm or less for a 100 nm thick film.

In summary, by growing epitaxially-strained SrCoO_{3-δ} thin films, we have found that oxygen non-stoichiometry critical for catalysis can be tailored by applying tensile strain to lower the equilibrium oxygen concentration. As tensile-strained films easily lose oxygen, we attribute this phenomenon to a weakened Co-O bond, resulting in an oxygen deficient state. The subject ability to control oxygen vacancies in even highly oxidizing electrochemical conditions can desirably be used such as to enhance the important oxygen evolution reaction by more than an order of magnitude. Thus it has been discovered that strain dictates the oxygen stoichiometry by controlling the activation energies in metastable strontium cobaltites and in view thereof precise control over physical and electrochemical properties via oxygen vacancies is herein encompassed and is realizable. Those skilled in the art and guided by the teachings herein provided will understand and appreciate that the discovery in the subject development of strong coupling of strain to oxygen defects provides a new route towards designing novel functional oxides where strain is a key tuning parameter.

The invention illustratively disclosed herein suitably may be practiced in the absence of any element, part, step, component, or ingredient which is not specifically disclosed herein.

While in the foregoing detailed description this invention has been described in relation to certain preferred embodiments thereof, and many details have been set forth for purposes of illustration, it will be apparent to those skilled in the art that the invention is susceptible to additional embodiments and that certain of the details described herein can be varied considerably without departing from the basic principles of the invention.

What is claimed is:

1. A method for tailoring an oxygen defect concentration in a transition metal oxide, the method comprising:
applying an epitaxial strain of up to 5% to the transition metal oxide to increase the oxygen defect concentration in the transition metal oxide and result in a product comprising the transition metal oxide having an increased oxygen defect concentration.

2. The method of claim 1 wherein the oxygen defect comprises oxygen vacancies.

3. The method of claim 1 wherein the applied epitaxial strain comprises a biaxial strain.

4. The method of claim 1 wherein said application of the epitaxial strain occurs at a temperature of 25-600° C.

5. The method of claim 1 wherein the epitaxial strain is applied in a value of at least 0.01%.

6. The method hod of claim 1 wherein the epitaxial strain is applied in a value of at least 0.1%.

7. The method of claim 1 wherein the epitaxial strain is applied in a range of 1-5%.

8. The method of claim 1 wherein the transition metal oxide comprises strontium cobaltite (SrCoO_{3-δ}, where 0≦δ≦0.25).

9. The method of claim 8 wherein prior to said application of the epitaxial strain, the transition metal oxide is provided as a thin film on a substrate and said application of the epitaxial strain comprises applying a biaxial strain to the thin film transition metal oxide.

10. The method of claim 8 wherein the application of the biaxial tensile strain to the thin film transition metal oxide reduces oxygen stoichiometry in the SrCoO_{3-δ} at highly anodic potentials in an alkaline solution.

11. The method of claim 10 wherein the application of the biaxial tensile strain to the thin film transition metal oxide produces a reduction in oxygen stoichiometry to SrCoO_{2.75}.

12. The method of claim 1 wherein the product is an oxygen evolution reaction catalyst.

13. A catalyst prepared by the method of claim 1.

14. A method for increasing an oxygen vacancy concentration in a transition metal oxide, the method comprising:
providing a thin film of the transition metal oxide on a substrate; and
applying a biaxial tensile strain of up to 5% to the thin film to increase the oxygen vacancy concentration in the transition metal oxide and result in a product comprising the transition metal oxide having an increased oxygen vacancy concentration.

15. The method of claim 14 wherein said application of the biaxial tensile strain occurs at a temperature of 25-600° C.

16. The method of claim 14 wherein the epitaxial strain is applied in a value of at least 0.1%.

17. The method of claim 14 wherein the biaxial tensile strain is applied in a range of 1-5%.

18. The method of claim 14 wherein the transition metal oxide comprises strontium cobaltite (SrCoO_{3-δ}, where 0≦δ≦0.25).

19. The method of claim 14 wherein the product comprises a catalyst.

20. The method of claim 19 wherein the product is an oxygen evolution reaction catalyst.
